(19) United States
(12) Patent Application Publication
(10) Pub. No.: US 2014/0084333 A1
(43) Pub. Date: Mar. 27, 2014

(54) POWER SEMICONDUCTOR DEVICE

(71) Applicant: KABUSHIKI KAISHA TOSHIBA, Minato-ku (JP)

(72) Inventors: Kazutoshi Nakamura, Hyogo-ken (JP); Tsuneo Ogura, Kanagawa-ken (JP); Hideaki Ninomiya, Hyogo-ken (JP)

(73) Assignee: KABUSHIKI KAISHA TOSHIBA, Minato-ku (JP)

(21) Appl. No.: 14/017,986

(22) Filed: Sep. 4, 2013

(30) Foreign Application Priority Data
Sep. 24, 2012 (JP) 2012-210035

(51) Int. Cl. H01L 29/739

(52) U.S. Cl. CPC H01L 29/7395
USPC 257/139

(57) ABSTRACT

In general, according to one embodiment, a power semiconductor device includes a first, a second, a third, a fourth, and a fifth electrode, and a first, a second, a third, and a fourth semiconductor layer. The first electrode includes a first and a second face. The first semiconductor layer is provided on a side of the first face of the first electrode. The second semiconductor layer is provided on the first semiconductor layer. The third semiconductor layer is provided on the second semiconductor layer. The fourth semiconductor layer is provided on the third semiconductor layer. The second electrode is electrically connected to the fourth semiconductor layer. The third and fourth electrode are provided at the second semiconductor layer and the third semiconductor layer with an insulating film interposed. The fifth electrode is provided between the third electrode and the fourth electrode with an insulating film interposed.

### CROSS-REFERENCE TO RELATED APPLICATIONS

This application is based upon and claims the benefit of priority from Japanese Patent Application No. 2012-210035, filed on Sep. 24, 2012; the entire contents of which are incorporated herein by reference.

### FIELD

Embodiments described herein relate generally to a power semiconductor device.

### BACKGROUND

Power semiconductor devices include IGBTs (Insulated Gate Bipolar Transistors), etc. Methods to reduce the on-voltage of the IGBT include a method in which the IE effect (carrier injection enhancement effect) is utilized. If the IE effect is utilized, a low on-voltage can be realized by increasing the discharge resistance of the holes to increase the carrier concentration on the emitter electrode side. The IE effect can be caused to occur by, for example, providing an n layer (an n barrier layer) between a p-type base layer and an n-type base layer, where the concentration of the impurity of the n layer is higher than that of the n-type base layer.

The on-voltage can be reduced by increasing the impurity concentration of the n barrier layer. However, when the impurity concentration of the n barrier layer is increased, problems occur such as, for example, the gate voltage oscillating at turn-on. The oscillation of the gate voltage becomes noise and has a negative effect on peripheral electronic devices. Also, when the gate voltage oscillates, it becomes difficult to control the temporal rate of change (dV/dt) of the collector-emitter voltage at turn-on. Thus, there is a trade-off relationship between the decrease of the on-voltage and the improvement of the switching characteristics (the controllability of the gate).

### BRIEF DESCRIPTION OF THE DRAWINGS

FIG. 1 is a schematic cross-sectional view illustrating a power semiconductor device according to a first embodiment;

FIG. 2A and FIG. 2B are schematic views illustrating the power semiconductor device according to the first embodiment;

FIG. 3 is an equivalent circuit diagram illustrating the power semiconductor device according to the first embodiment;

FIG. 4A to FIG. 4F are schematic cross-sectional views in order of processes illustrating the processes of a method for manufacturing the power semiconductor device according to the first embodiment;

FIG. 5A to FIG. 5F are schematic cross-sectional views in order of the processes illustrating the processes of the method for manufacturing the power semiconductor device according to the first embodiment;

FIG. 6 is a schematic cross-sectional view illustrating a first variation of the power semiconductor device according to the first embodiment;

FIG. 7A and FIG. 7B are schematic views illustrating a second variation of the power semiconductor device according to the first embodiment;

FIG. 8 is a schematic cross-sectional view illustrating a power semiconductor device according to a second embodiment;

FIG. 9A and FIG. 9B are schematic views illustrating the power semiconductor device according to the second embodiment;

FIG. 10 is a schematic cross-sectional view illustrating a variation of the power semiconductor device according to the second embodiment; and

FIG. 11 is a schematic cross-sectional view illustrating a power semiconductor device according to a third embodiment.

### DETAILED DESCRIPTION

In general, according to one embodiment, a power semiconductor device includes a first electrode, a first semiconductor layer, a second semiconductor layer, a third semiconductor layer, a fourth semiconductor layer, a second electrode, a third electrode, a fourth electrode, and a fifth electrode. The first electrode includes a first face and a second face. The first semiconductor layer is provided on the first face of the first electrode and is a first conductivity type. The second semiconductor layer is provided on the first semiconductor layer and a concentration of an impurity of the second semiconductor layer is higher than a concentration of an impurity of the first semiconductor layer. The second semiconductor layer is the first conductivity type. The third semiconductor layer is provided on the second semiconductor layer and is a second conductivity type. The fourth semiconductor layer is provided on the third semiconductor layer and the first conductivity type. The second electrode is electrically connected to the fourth semiconductor layer. The third electrode is provided at the second semiconductor layer and the third semiconductor layer with an insulating film interposed between the third electrode and the second semiconductor layer and between the third electrode and the third semiconductor layer. The third electrode extends in a stacking direction of the first semiconductor layer and the second semiconductor layer to have an upper end positioned at the third semiconductor layer. The fourth electrode is arranged with the third electrode to be provided at the second semiconductor layer and the third semiconductor layer with an insulating film interposed between the fourth electrode and the second semiconductor layer and between the fourth electrode and the third semiconductor layer. The fourth electrode extends in the stacking direction and an upper end of the fourth electrode positioned at the third semiconductor layer. The fifth electrode is provided between the third electrode and the fourth electrode with an insulating film interposed between the fifth electrode and the third electrode and between the fifth electrode and the fourth electrode. The fifth electrode is electrically connected to the second electrode and extends in the stacking direction and an upper end of the fifth electrode positioned at the third semiconductor layer.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

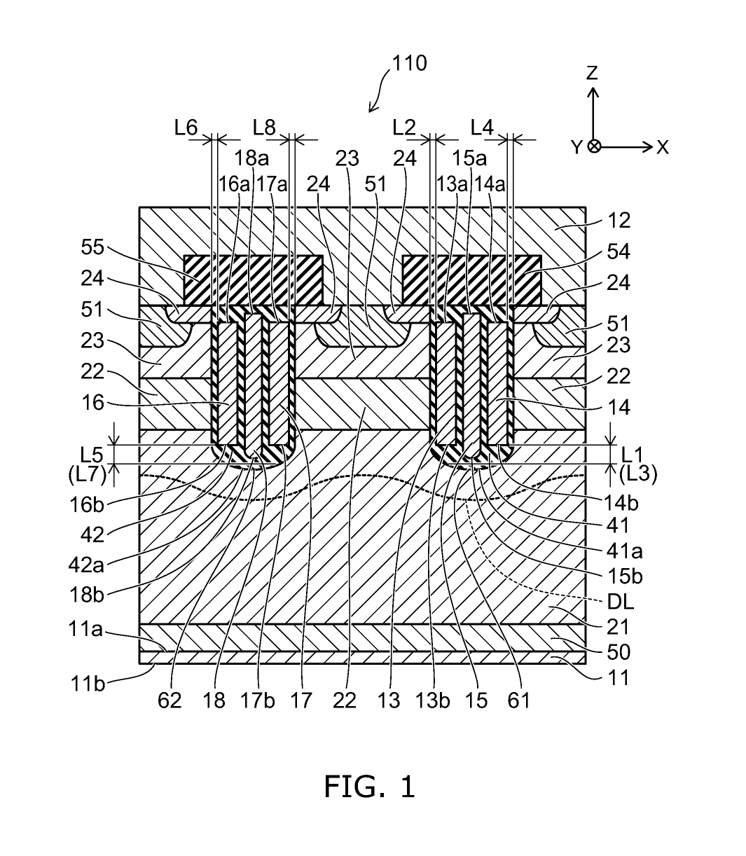

FIG. 1 is a schematic cross-sectional view illustrating a power semiconductor device according to a first embodiment.

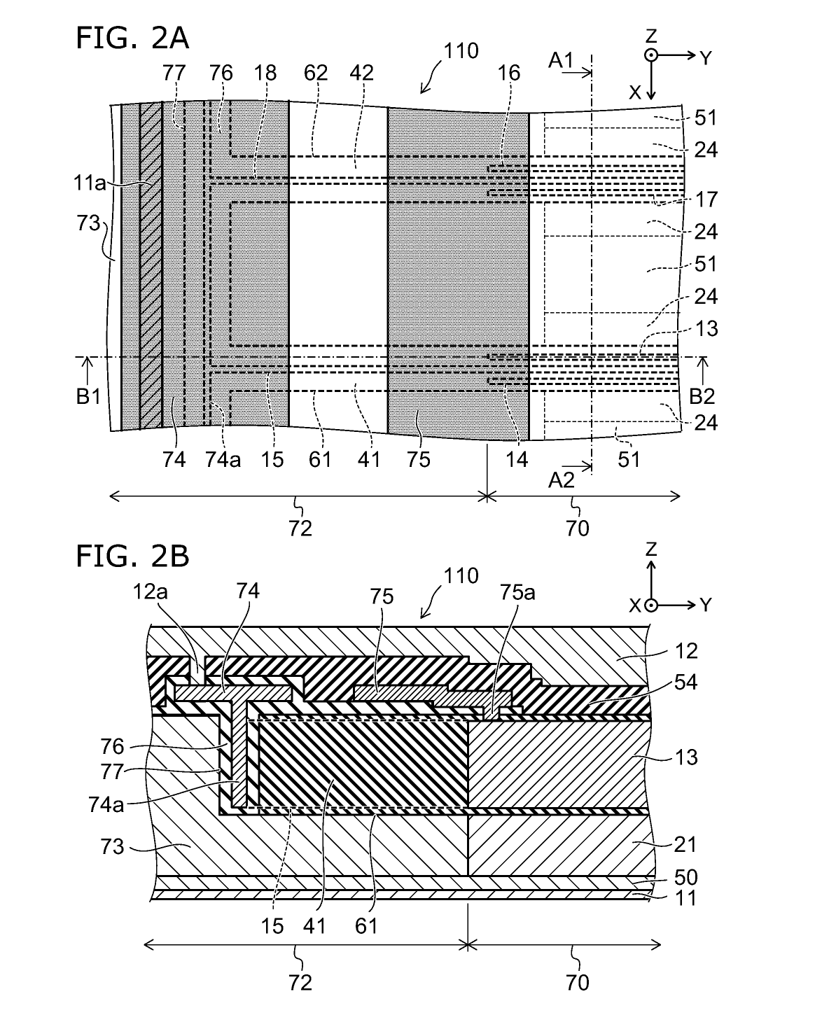

FIG. 2A and FIG. 2B are schematic views illustrating the power semiconductor device according to the first embodiment.

FIG. 2A is a schematic plan view; and FIG. 2B is a schematic cross-sectional view. FIG. 1 shows a cross section along line A1-A2 of FIG. 2A. FIG. 2B shows a cross section along line B1-B2 of FIG. 2A.

As shown in FIG. 1, the IGBT 110 (the power semiconductor device) includes a collector electrode 11 (a first electrode), an emitter electrode 12 (a second electrode), an electrode 13 (a third electrode), an electrode 14 (a fourth electrode), an electrode 15 (a fifth electrode), an n⁻ base layer 21 (a first semiconductor layer), an n barrier layer 22 (a second semiconductor layer), a p base layer 23 (a third semiconductor layer), and an n⁺ emitter layer 24 (a fourth semiconductor layer). The IGBT 110 has, for example, a trench-gate structure.

The collector electrode 11 has a first surface 11a and a second surface 11b.

The n⁻ base layer 21 is provided on the first surface 11a side of the collector electrode 11. The n⁻ base layer 21 is the n type (the first conductivity type). The first conductivity type may be the p type. In such a case, the second conductivity type is the n type.

The n barrier layer 22 is the n type and is provided on the n⁻ base layer 21. The n barrier layer 22 extends in the X-axis direction and the Y-axis direction. The concentration of the impurity of the n barrier layer 22 is higher than the concentration of the impurity of the n⁻ base layer 21.

Herein, the stacking direction of the n⁻ base layer 21 and the n barrier layer 22 is taken as a Z-axis direction. One direction perpendicular to the Z-axis direction is taken as an X-axis direction. A direction perpendicular to the Z-axis direction and the X-axis direction is taken as a Y-axis direction. In the specification of the application, “up” is the direction from the n⁻ base layer 21 toward the n barrier layer 22; and “down” is the direction from the n barrier layer 22 toward the n⁻ base layer 21.

The p base layer 23 is the p type and is provided on the n barrier layer 22. The p base layer 23 extends in the X-axis direction and the Y-axis direction.

The n⁺ emitter layer 24 is the n type and is provided on the p base layer 23. The n⁺ emitter layer 24 extends in the X-axis direction and the Y-axis direction. The concentration of the impurity of the n⁺ emitter layer 24 is higher than the concentration of the impurity of the n⁻ base layer 21. The n⁺ emitter layer 24 is electrically connected to the emitter electrode 12. The n⁺ emitter layer 24 is electrically connected to the emitter electrode 12 by, for example, being in contact with the emitter electrode 12. In the specification of the application, being “electrically connected” includes not only being connected in direct contact but also includes being connected via another conductive member, etc.

The emitter electrode 12 is provided on the n⁺ emitter layer 24. The emitter electrode 12 may include, for example, aluminum. The collector electrode 11 may include, for example, a metal material such as V, Ni, Au, Ag, Sn, etc. The n⁻ base layer 21, the n barrier layer 22, the p base layer 23, and the n⁺ emitter layer 24 may include, for example, a semiconductor such as silicon, etc., a compound semiconductor such as silicon carbide (SiC), gallium nitride (GaN), etc., a wide bandgap semiconductor such as diamond, etc.

The electrode 13 is provided at the n barrier layer 22 and the p base layer 23 with an insulating film 41 interposed between the electrode 13 and the n barrier layer 22 and between the electrode 13 and the p base layer 23. The electrode 13 extends along the Z-axis direction and the Y-axis direction. An upper end 13a of the electrode 13 is positioned at the p base layer 23. The upper end 13a of the electrode 13 may be positioned higher than the p base layer 23. A lower end 13b of the electrode 13 is positioned lower than the n barrier layer 22. The electrode 13 opposes in the X-axis direction the entire Z-axis direction length of the p base layer 23 and the entire Z-axis direction length of the n barrier layer 22.

The electrode 14 is provided at the n barrier layer 22 and the p base layer 23 with the insulating film 41 interposed between the electrode 14 and the n barrier layer 22 and between the electrode 14 and the p base layer 23. The electrode 14 extends along the Z-axis direction and the Y-axis direction. An upper end 14a of the electrode 14 is positioned at the p base layer 23. The upper end 14a of the electrode 14 may be positioned higher than the p base layer 23. A lower end 14b of the electrode 14 is positioned lower than the n barrier layer 22. The electrode 14 opposes in the X-axis direction the entire Z-axis direction length of the p base layer 23 and the entire Z-axis direction length of the n barrier layer 22.

The electrode 15 is provided between the electrode 13 and the electrode 14 in the X-axis direction with the insulating film 41 interposed between the electrode 15 and the electrode 13 and between the electrode 15 and the electrode 14. The electrode 15 extends along the Z-axis direction and the Y-axis direction. An upper end 15a of the electrode 15 is positioned at the p base layer 23. The upper end 15a of the electrode 15 may be positioned higher than the upper end 13a and the upper end 14a. A lower end 15b of the electrode 15 is positioned lower than the lower end 13b and the lower end 14b. The Z-axis direction position of the upper end 15a and the Z-axis direction position of the lower end 15b may be any position.

In the embodiment, the electrode 13 and the electrode 14 are electrically connected to a not-shown gate electrode; and the electrode 15 is electrically connected to the emitter electrode 12. In the embodiment hereinbelow, the electrode 13 and the electrode 14 are called the gate electrode 13 and the gate electrode 14, respectively; and the electrode 15 is called the emitter electrode 15. The gate electrode 13, the gate electrode 14, and the emitter electrode 15 may include, for example, polysilicon.

The insulating film 41 is provided between the n⁻ base layer 21 and the gate electrode 13, between the n barrier layer 22 and the gate electrode 13, between the p base layer 23 and the gate electrode 13, between the n⁺ emitter layer 24 and the gate electrode 13, between the n⁻ base layer 21 and the gate electrode 14, between the n barrier layer 22 and the gate electrode 14, between the p base layer 23 and the gate electrode 14, between the n⁺ emitter layer 24 and the gate electrode 14, between the n⁻ base layer 21 and the emitter electrode 15, between the gate electrode 13 and the emitter electrode 15, and between the gate electrode 14 and the emitter electrode 15.

In other words, the insulating film 41 electrically insulates the n⁻ base layer 21 from the gate electrode 13, electrically insulates the n barrier layer 22 from the gate electrode 13, electrically insulates the p base layer 23 from the gate electrode 13, electrically insulates the n⁺ emitter layer 24 from the gate electrode 13, electrically insulates the n⁻ base layer 21 from the gate electrode 14, electrically insulates the n barrier layer 22 from the gate electrode 14, electrically insulates the p base layer 23 from the gate electrode 14, electrically insulates the n⁺ emitter layer 24 from the gate electrode 14, electrically insulates the n⁻ base layer 21 from the emitter electrode 15, electrically insulates the gate electrode 13 from the emitter electrode 15, and electrically insulates the gate electrode 14 from the emitter electrode 15.

The insulating film 41 may include, for example, a silicon oxide film, a silicon nitride film, a silicon oxynitride film, etc.

A distance L1 (a first distance) along the Z-axis direction between the n⁻ base layer 21 and the lower end 13b of the gate electrode 13 is longer than a distance L2 (a second distance) along the X-axis direction between the gate electrode 13 and the p base layer 23. In other words, the thickness along the Z-axis direction of the insulating film 41 between the n⁻ base layer 21 and the lower end 13b of the gate electrode 13 is thicker than the thickness along the X-axis direction of the insulating film 41 between the gate electrode 13 and the p base layer 23.

Also, a distance L3 (a third distance) along the Z-axis direction between the n⁻ base layer 21 and the lower end 14b of the gate electrode 14 is longer than a distance L4 (a fourth distance) along the X-axis direction between the gate electrode 14 and the p base layer 23. In other words, the thickness along the Z-axis direction of the insulating film 41 between the n⁻ base layer 21 and the lower end 14b of the gate electrode 14 is thicker than the thickness along the X-axis direction of the insulating film 41 between the gate electrode 14 and the p base layer 23.

In the embodiment, the absolute value of the difference between the distance L1 and the distance L3 is not more than 5 nm. In other words, the distance L1 is substantially the same as the distance L3. The absolute value of the difference between the distance L2 and the distance L4 is not more than 5 nm. In other words, the distance L2 is substantially the same as the distance L4. The distance L1 and the distance L3 change in the X-axis direction. The distance L1 is taken to be, for example, the average distance along the Z-axis direction between the n⁻ base layer 21 and the lower end 13b of the gate electrode 13. The distance L3 is taken to be, for example, the average distance along the Z-axis direction between the n⁻ base layer 21 and the lower end 14b of the gate electrode 14. The distance L1 and the distance L3 are, for example, not less than 0.5 μm and not more than 5 μm. The distance L2 and the distance L4 are, for example, not less than 50 nm and not more than 300 nm.

The IGBT 110 further includes an electrode 16 (a sixth electrode), an electrode 17 (a seventh electrode), and an electrode 18 (an eighth electrode).

The electrode 16 is provided at the n barrier layer 22 and the p base layer 23 with an insulating film 42 interposed between the electrode 16 and the n barrier layer 22 and between the electrode 16 and the p base layer 23. The electrode 16 extends along the Z-axis direction and the Y-axis direction. An upper end 16a of the electrode 16 is positioned at the p base layer 23. The upper end 16a of the electrode 16 may be positioned higher than the p base layer 23. A lower end 16b of the electrode 16 is positioned lower than the n barrier layer 22. The electrode 16 opposes in the X-axis direction the entire Z-axis direction length of the p base layer 23 and the entire Z-axis direction length of the n barrier layer 22.

The electrode 17 is provided at the n barrier layer 22 and the p base layer 23 with the insulating film 42 interposed between the electrode 17 and the n barrier layer 22 and between the electrode 17 and the p base layer 23. The electrode 17 extends along the Z-axis direction and the Y-axis direction. An upper end 17a of the electrode 17 is positioned at the p base layer 23. The upper end 17a of the electrode 17 may be positioned higher than the p base layer 23. A lower end 17b of the electrode 17 is positioned lower than the n barrier layer 22. The electrode 17 opposes in the X-axis direction the entire Z-axis direction length of the p base layer 23 and the entire Z-axis direction length of the n barrier layer 22.

The electrode 18 is provided between the electrode 16 and the electrode 17 with the insulating film 42 interposed between the electrode 18 and the electrode 16 and between the electrode 18 and the electrode 17. The electrode 18 extends along the Z-axis direction and the Y-axis direction. An upper end 18a of the electrode 18 is positioned at the p base layer 23. The upper end 18a of the electrode 18 may be positioned higher than the upper end 16a and the upper end 17a. A lower end 18b of the electrode 18 is positioned lower than the lower end 16b and the lower end 17b. The Z-axis direction position of the upper end 18a and the Z-axis direction position of the lower end 18b may be any position.

In the embodiment, the electrode 16 and the electrode 17 are electrically connected to the gate electrode 13 and are electrically connected to a not-shown gate electrode; and the electrode 18 is electrically connected to the emitter electrode 12. In other words, the gate electrode 13, the gate electrode 14, the electrode 16, and the electrode 17 are set to have substantially the same potential; and the emitter electrode 12, the emitter electrode 15, and the electrode 18 are set to have substantially the same potential. In the embodiment hereinbelow, the electrode 16 and the electrode 17 are called the gate electrode 16 and the gate electrode 17, respectively; and the electrode 18 is called the emitter electrode 18. The gate electrode 16, the gate electrode 17, and the emitter electrode 18 may include, for example, polysilicon.

The insulating film 42 is provided between the n⁻ base layer 21 and the gate electrode 16, between the n barrier layer 22 and the gate electrode 16, between the p base layer 23 and the gate electrode 16, between the n⁺ emitter layer 24 and the gate electrode 16, between the n⁻ base layer 21 and the gate electrode 17, between the n barrier layer 22 and the gate electrode 17, between the p base layer 23 and the gate electrode 17, between the n⁺ emitter layer 24 and the gate electrode 17, between the n⁻ base layer 21 and the emitter electrode 18, between the gate electrode 16 and the emitter electrode 18, and between the gate electrode 17 and the emitter electrode 18.

In other words, the insulating film 42 electrically insulates the n⁻ base layer 21 from the gate electrode 16, electrically insulates the n barrier layer 22 from the gate electrode 16, electrically insulates the p base layer 23 from the gate electrode 16, electrically insulates the n⁺ emitter layer 24 from the gate electrode 16, electrically insulates the n⁻ base layer 21 from the gate electrode 17, electrically insulates the n barrier layer 22 from the gate electrode 17, electrically insulates the p base layer 23 from the gate electrode 17, electrically insulates the n⁺ emitter layer 24 from the gate electrode 17, electrically insulates the n⁻ base layer 21 from the emitter electrode 18, electrically insulates the gate electrode 16 from the emitter electrode 18, and electrically insulates the gate electrode 17 from the emitter electrode 18.

The insulating film 42 may include, for example, a silicon oxide film, a silicon nitride film, a silicon oxynitride film, etc.

A distance L5 (a fifth distance) along the Z-axis direction between the n⁻ base layer 21 and the lower end 16b of the gate electrode 16 is longer than a distance L6 (a sixth distance) along the X-axis direction between the gate electrode 16 and the p base layer 23. In other words, the thickness along the Z-axis direction of the insulating film 42 between the n⁻ base layer 21 and the lower end 16b of the gate electrode 16 is thicker than the thickness along the X-axis direction of the insulating film 42 between the gate electrode 16 and the p base layer 23.

Also, a distance L7 (a seventh distance) along the Z-axis direction between the n⁻ base layer 21 and the lower end 17b of the gate electrode 17 is longer than a distance L8 (an eighth distance) along the X-axis direction between the gate electrode 17 and the p base layer 23. In other words, the thickness along the Z-axis direction of the insulating film 42 between the n⁻ base layer 21 and the lower end 17b of the gate electrode 17 is thicker than the thickness along the X-axis direction of the insulating film 42 between the gate electrode 17 and the p base layer 23.

In the embodiment, the absolute value of the difference between the distance L5 and the distance L7 is not more than 5 nm. In other words, the distance L5 is substantially the same as the distance L7. The absolute value of the difference between the distance L6 and the distance L8 is not more than 5 nm. In other words, the distance L6 is substantially the same as the distance L8. The distance L1 and the distance L3 change in the X-axis direction. The distance L5 is, for example, the average distance along the Z-axis direction between the n⁻ base layer 21 and the lower end 16b of the gate electrode 16. The distance L7 is, for example, the average distance along the Z-axis direction between the n⁻ base layer 21 and the lower end 17b of the gate electrode 17. The distance L5 and the distance L7 are substantially the same as the distance L1 and the distance L3. The distance L6 and the distance L8 are substantially the same as the distance L2 and the distance L4.

The IGBT 110 further includes a p⁺ collector layer 50 (a fifth semiconductor layer), a p⁺ contact layer 51, an insulating film 54, an insulating film 55, a trench 61, and a trench 62.

The p⁺ collector layer 50 is the p type and is provided between the collector electrode 11 and the n⁻ base layer 21. The p⁺ collector layer 50 is electrically connected to the collector electrode 11 and the n⁻ base layer 21.

The p⁺ contact layer 51 is the p type and is provided between the emitter electrode 12 and the p base layer 23. For example, the p⁺ contact layer 51 is multiply provided between the emitter electrode 12 and the p base layer 23. The p⁺ contact layer 51 extends along the Y-axis direction. The concentration of the impurity of the p⁺ contact layer 51 is higher than the concentration of the impurity of the p base layer 23. The p⁺ contact layer 51 is electrically connected to the emitter electrode 12 and the p base layer 23. Thereby, the p base layer 23 is electrically connected to the emitter electrode 12 via the p⁺ contact layer 51. Thereby, for example, the holes stored in the p base layer 23 become easy to discharge to the emitter electrode 12.

The insulating film 54 is provided between the emitter electrode 12 and the insulating film 41. For example, the insulating film 54 increases the insulative property between the emitter electrode 12 and the gate electrode 13 and the insulative property between the emitter electrode 12 and the gate electrode 14.

The insulating film 55 is provided between the emitter electrode 12 and the insulating film 42. For example, the insulating film 55 increases the insulative property between the emitter electrode 12 and the gate electrode 16 and the insulative property between the emitter electrode 12 and the gate electrode 17.

The insulating film 54 and the insulating film 55 may include, for example, a silicon oxide film, a silicon nitride film, a silicon oxynitride film, etc.

The trench 61 is provided in the n⁻ base layer 21, the n barrier layer 22, and the p base layer 23. The trench 61 extends along the Z-axis direction and the Y-axis direction. The gate electrode 13, the gate electrode 14, the emitter electrode 15, and the insulating film 41 are provided in the interior of the trench 61.

The trench 62 is provided in the n⁻ base layer 21, the n barrier layer 22, and the p base layer 23. The trench 62 extends along the Z-axis direction and the Y-axis direction. The gate electrode 16, the gate electrode 17, the emitter electrode 18, and the insulating film 42 are provided in the interior of the trench 62.

For example, the n⁺ emitter layer 24 is multiply provided on the p base layer 23. One of the multiple n⁺ emitter layers 24 is provided between the insulating film 41 and the p⁺ contact layer 51 in the X-axis direction. The one of the n⁺ emitter layers 24 is disposed to be proximal to the insulating film 41 (the trench 61). For example, the one of the n⁺ emitter layers 24 contacts the insulating film 41 in the X-axis direction.

Also, one other of the multiple n⁺ emitter layers 24 is provided between the insulating film 42 and the p⁺ contact layer 51 in the X-axis direction. The one other of the n⁺ emitter layers 24 is disposed to be proximal to the insulating film 42 (the trench 62). For example, the one other of the n⁺ emitter layers 24 contacts the insulating film 42 in the X-axis direction.

As shown in FIG. 2A and FIG. 2B, the IGBT 110 has a device region 70 and a terminal region 72.

The n⁻ base layer 21, the n barrier layer 22, the p base layer 23, and the n⁺ emitter layers 24 are provided in the device region 70. The device region 70 is a region where the current flows between the collector electrode 11 and the emitter electrode 12.

The terminal region 72 is provided around the device region 70 by being provided around an axis extending in the Z-axis direction. The emitter electrode 12, the insulating film 54, the insulating film 55, etc., are not shown in FIG. 2A for convenience.

A p-type layer 73, an emitter interconnect 74, a gate interconnect 75, a terminal insulating film 76, and a terminal trench 77 are provided in the terminal region 72.

The p-type layer 73 is the p type and is provided between the collector electrode 11 and the emitter electrode 12. For example, the p-type layer 73 is a diffusion layer that is deeper than the p base layer 23.

The emitter interconnect 74 is provided between the emitter electrode 12 and the p-type layer 73. The emitter interconnect 74 may include, for example, a conductive material such as polysilicon, etc. Insulating layers such as the insulating film 54, the insulating film 55, the terminal insulating film 76, etc., are provided between the emitter electrode 12 and the emitter interconnect 74. A plug portion 12a is provided in the emitter electrode 12. The plug portion 12a extends along the Z-axis direction and the X-axis direction to contact the emitter interconnect 74. For example, the plug portion 12a pierces the insulating layer provided between the emitter electrode 12 and the emitter interconnect 74. Thereby, the emitter interconnect 74 is electrically connected to the emitter electrode 12.

A plug portion 74a extending along the Z-axis direction and the X-axis direction is provided in the emitter interconnect 74. The emitter electrode 15 extends along the Y-axis direction to contact the plug portion 74a. The emitter electrode 18 extends along the Y-axis direction to contact the plug portion 74a. Thereby, the emitter electrode 15 and the emitter electrode 18 are electrically connected to the emitter electrode 12 via the emitter interconnect 74. In the example, the emitter electrode 15 and the emitter electrode 18 are continuous with the plug portion 74a.

The terminal insulating film 76 is provided between the p-type layer 73 and the emitter interconnect 74 to electrically insulate the p-type layer 73 from the emitter interconnect 74. The terminal insulating film 76 may include, for example, a silicon oxide film, a silicon nitride film, a silicon oxynitride film, etc.

The terminal trench 77 extends along the Z-axis direction and the X-axis direction. The trench 61 and the trench 62 communicate with the terminal trench 77. The plug portion 74a is provided in the interior of the terminal trench 77. A portion of the terminal insulating film 76 is provided in the interior of the terminal trench 77 to electrically insulate the p-type layer 73 from the plug portion 74a.

The gate interconnect 75 is provided between the emitter electrode 12 and the p-type layer 73 and is disposed to be separated from the emitter interconnect 74. Insulating layers such as the insulating film 54, the insulating film 55, etc., are provided between the emitter electrode 12 and the gate interconnect 75. Thereby, the gate interconnect 75 is electrically insulated from the emitter electrode 12. Insulating layers such as the terminal insulating film 76, etc., are provided between the p-type layer 73 and the gate interconnect 75. Thereby, the gate interconnect 75 is electrically insulated from the p-type layer 73.

Also, the gate interconnect 75 is provided on a portion of the gate electrode 13, on a portion of the gate electrode 14, on a portion of the gate electrode 16, and on a portion of the gate electrode 17. The terminal insulating film 76 and the insulating film 41 are provided between the gate interconnect 75 and the gate electrode 13. The terminal insulating film 76 and the insulating film 41 are provided between the gate interconnect 75 and the gate electrode 14. The terminal insulating film 76 and the insulating film 42 are provided between the gate interconnect 75 and the gate electrode 16. The terminal insulating film 76 and the insulating film 42 are provided between the gate interconnect 75 and the gate electrode 17.

A plug portion 75a is provided in the gate interconnect 75 to extend along the Z-axis direction to contact the gate electrode 13. A plug portion that contacts the gate electrode 14, a plug portion that contacts the gate electrode 16, and a plug portion that contacts the gate electrode 17 (these plug portions are not shown) are further provided in the gate interconnect 75. Thereby, the gate electrode 13, the gate electrode 14, the gate electrode 16, and the gate electrode 17 are electrically connected to each other via the gate interconnect 75.

The terminal insulating film 76 and the insulating film 41 are provided between the gate interconnect 75 and the emitter electrode 15. The terminal insulating film 76 and the insulating film 42 are provided between the gate interconnect 75 and the emitter electrode 18. Thereby, the gate interconnect 75 is electrically insulated from the emitter electrode 15 and the emitter electrode 18.

The gate interconnect 75 may include, for example, a conductive material such as polysilicon, etc. The gate interconnect 75 is electrically connected to a not-shown metal electrode (terminal electrode) in the terminal region 72.

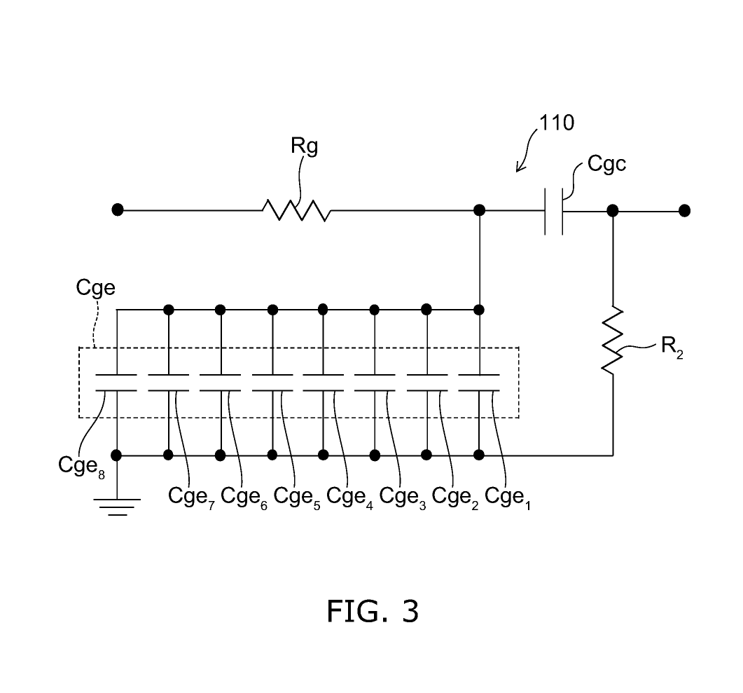

FIG. 3 is an equivalent circuit diagram illustrating the power semiconductor device according to the first embodiment.

As shown in FIG. 3, a gate resistance Rg, a capacitance Cge, a capacitance Cgc, and a resistance R₂ are provided in the IGBT 110.

The gate resistance Rg is a resistance that is electrically connected to the gate electrode 13, the gate electrode 14, the gate electrode 16, and the gate electrode 17. The capacitance Cge is a parasitic capacitance occurring between the gate and the emitter. The capacitance Cgc is a parasitic capacitance occurring between the gate and the collector. The resistance R₂ is an output resistance between the emitter and the collector.

The capacitance Cge includes a parasitic capacitance Cge₁ occurring between the emitter electrode 12 and the gate electrode 13, a parasitic capacitance Cge₂ occurring between the emitter electrode 12 and the gate electrode 14, a parasitic capacitance Cge₃ occurring between the emitter electrode 12 and the gate electrode 16, a parasitic capacitance Cge₄ occurring between the emitter electrode 12 and the gate electrode 17, a parasitic capacitance Cge₅ occurring between the gate electrode 13 and the emitter electrode 15, a parasitic capacitance Cge₆ occurring between the gate electrode 14 and the emitter electrode 15, a parasitic capacitance Cge₇ occurring between the gate electrode 16 and the emitter electrode 18, and a parasitic capacitance Cge₈ occurring between the gate electrode 17 and the emitter electrode 18. The capacitance Cge is Cge₁+Cge₂+Cge₃+Cge₄+Cge₅+Cge₆+Cge₇+Cgeₛ.

The capacitance Cge can be large by providing the emitter electrode 15 and the emitter electrode 18. For example, the capacitance Cge can be adjusted by adjusting the surface area of the portion of the gate electrode 13 opposing the emitter electrode 15, adjusting the surface area of the portion of the gate electrode 14 opposing the emitter electrode 15, adjusting the surface area of the portion of the gate electrode 16 opposing the emitter electrode 18, or adjusting the surface area of the portion of the gate electrode 17 opposing the emitter electrode 18.

Operations of the IGBT 110 will now be described.

For example, a positive voltage is applied to the collector electrode 11; and the emitter electrode 12 is grounded. Also, a positive voltage is applied to the gate electrode 13, the gate electrode 14, the gate electrode 16, and the gate electrode 17. Thereby, a current flows between the collector electrode 11 and the emitter electrode 12. When a voltage equal to or greater than the threshold voltage is applied to the gate electrode 13, the gate electrode 14, the gate electrode 16, and the gate electrode 17, an inversion channel is formed in the region of the p base layer 23 proximal to the insulating film 41 and in the region of the p base layer 23 proximal to the insulating film 42. For example, the current flows from the collector electrode 11 to the emitter electrode 12 by way of the p⁺ collector layer 50, the n⁻ base layer 21, the inversion channel, and the n⁺ emitter layer 24.

Effects of the IGBT 110 will now be described.

By providing the n barrier layer 22, the discharge resistance of the holes flowing in the emitter electrode 12 can be increased. In other words, the IE effect is obtained. Thereby, the injection efficiency of the electrons from the emitter electrode 12 is increased; and the carrier concentration on the emitter electrode 12 side is increased. Thereby, a high breakdown voltage and a low on-voltage can be realized. The on-voltage can be reduced further by increasing the concentration of the impurity of the n barrier layers 22. There are cases where the IGBT 110 utilizing the IE effect is called an IEGT (injection-Enhanced Gate Bipolar Transistor).

In some IGBTs, only the gate electrode 13 is provided inside the trench 61; the distance L1 is set to be substantially the same as the distance L2 (the film thickness of the insulating film 41 is set to be uniform); only the gate electrode 16 is provided inside the trench 62; and the distance L5 is set to be substantially the same as the distance L6 (the film thickness of the insulating film 42 is set to be uniform). The IGBT of the reference example is problematic in that the gate voltage oscillates at turn-on. In the reference example, the oscillation of the gate voltage becomes more pronounced by increasing the concentration of the impurity of the n barrier layers 22. In other words, in the reference example, there is a trade-off relationship between the decrease of the on-voltage and the improvement of the switching characteristics.

The n barrier layer 22 is used as a barrier to the holes from the collector electrode 11 toward the emitter electrode 12. Also, in the reference example, for example, a voltage of about 650 V is applied to the collector electrode 11; and a voltage of about 15 V is applied to the gate electrode 13 and the gate electrode 16. In other words, the collector voltage is sufficiently large with respect to the gate voltage. Therefore, when the holes flow from the collector electrode 11 toward the emitter electrode 12, the holes are attracted by the gate voltage to flow through the portion of the n barrier layer proximal to the gate electrode. At this time, a displacement current flows in the gate electrode via the capacitance Cgc between the gate and the collector. The displacement current causes the gate voltage to oscillate. At turn-on, the current flowing from the gate electrode is considered to be for a negative capacitance with respect to the current that normally flows into the gate electrode.

The gate voltage oscillates when the condition of Formula (1) is satisfied.

$$gm > \frac{1}{Rg} + \frac{1}{{R}_{2}} ( 1 + \frac{Cge}{Cgc} ) \qquad [ Formula 1 ]$$

As shown in Formula (1), the oscillation of the gate voltage correlates with a transconductance gm, the gate resistance Rg, the output resistance R₂, the capacitance Cge, and the capacitance Cgc of the IGBT 110. The oscillation of a gate voltage Vg is proportional to the magnitude of the transconductance gm. In the state in which the relationship of Formula (1) holds, the gate voltage Vg oscillates more markedly as the difference between the left side and the right side of Formula (1) increases.

In the IGBT 110 according to the embodiment of the application, the capacitance Cge can be large due to the emitter electrode 15 and the emitter electrode 18. Thereby, in the IGBT 110, the right side of the inequality formula of Formula (1) can be large. In other words, the oscillation of the gate voltage can be suppressed even when the displacement current flows in the gate electrode 13, the gate electrode 14, the gate electrode 16, and the gate electrode 17 due to the holes flowing through the vicinity of the gate electrodes. Thereby, in the IGBT 110, the concentration of the impurity of the n barrier layer 22 can be increased. In the IGBT 110, the trade-off between the decrease of the on-voltage and the improvement of the switching characteristics can be improved. In the IGBT 110, a power semiconductor device having good switching characteristics and a low on-voltage is obtained.

Further, in the IGBT 110, the capacitance Cgc can be small by setting the distance L1 to be longer than the distance L2, by setting the distance L3 to be longer than the distance L4, by setting the distance L5 to be longer than the distance L6, and by setting the distance L7 to be longer than the distance L8. Thereby, in the IGBT 110, the occurrence of the displacement current caused by the capacitance Cgc can be suppressed; and the oscillation of the gate voltage can be suppressed more appropriately. Also, the capacitance Cgc can be reduced to reduce the ratio Cgc/Cge with the capacitance Cge. Thereby, the oscillation of the gate voltage when the displacement current flows can be suppressed more appropriately. Further, in the IGBT 110, the distance L1 is substantially the same as the distance L3; and the distance L2 is substantially the same as the distance L4. Thereby, for example, the formation of the IGBT 110 is easier.

A method for manufacturing the IGBT 110 will now be described.

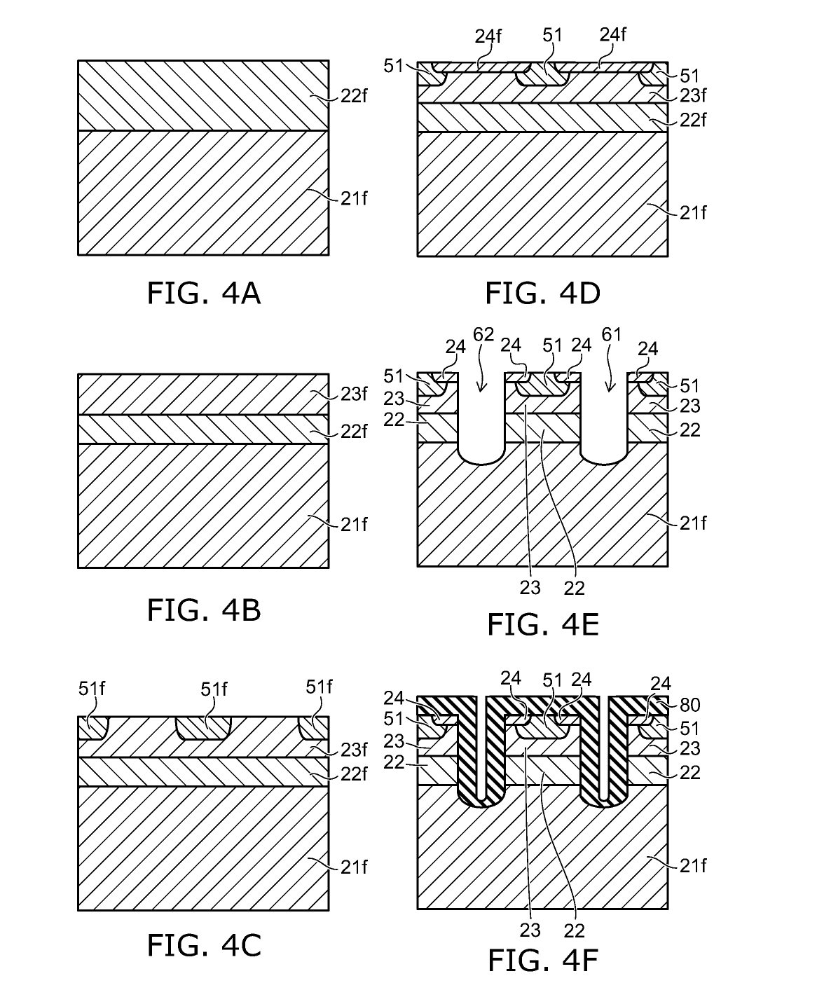

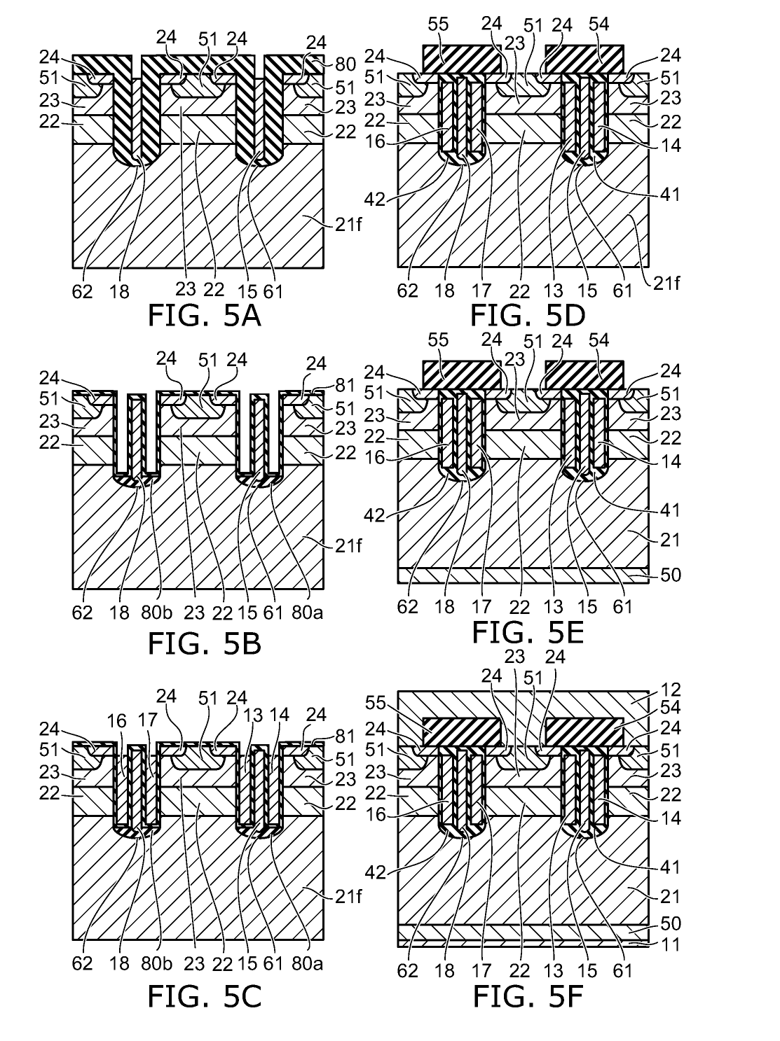

FIG. 4A to FIG. 4F and FIG. 5A to FIG. 5F are schematic cross-sectional views in order of the processes, illustrating processes of the method for manufacturing the power semiconductor device according to the first embodiment.

As shown in FIG. 4A, an n barrier film 22f that is used to form the n barrier layer 22 is formed by ion implantation in the region of the upper portion of an n-type semiconductor substrate 21f that is used to form the n⁻ base layer 21. The n barrier film 22f may be formed on the n-type semiconductor substrate 21f by, for example, epitaxial growth.

As shown in FIG. 4B, a p base film 23f that is used to form the p base layer 23 is formed by ion implantation in the region of the upper portion of the n barrier film 22f. The p base film 23f may be formed on the n barrier film 22f by, for example, epitaxial growth.

As shown in FIG. 4C, multiple p-type regions 51f that are used to form the p⁺ contact layers 51 are formed by photolithography and ion implantation in the region of the upper portion of the p base film 23f.

As shown in FIG. 4D, multiple n-type regions 24f that are used to form the n⁺ emitter layers 24 are formed respectively in each space between two mutually adjacent p-type regions 51f in the region of the upper portion of the p base film 23f by photolithography and ion implantation. Thereby, the p⁺ contact layer 51 is formed from the p-type region 51f.

As shown in FIG. 4E, the trench 61 and the trench 62 are made by photolithography and etching. For example, the trench 61 and the trench 62 are made to pierce the n-type region 24f, the p base film 23f, and the n barrier film 22f to reach the n-type semiconductor substrate 21f. Thereby, the n barrier layer 22 is formed from the n barrier film 22f. The p base layer 23 is formed from the p base film 23f. The n⁺ emitter layer 24 is formed from the n-type region 24f.

As shown in FIG. 4F, an insulating layer 80 that is used to form a portion of the insulating film 41 and a portion of the insulating film 42 is formed on the n-type semiconductor substrate 21f. A portion of the insulating layer 80 is provided along the inner wall of the trench 61. One other portion of the insulating layer 80 is provided along the inner wall of the trench 62.

As shown in FIG. 5A, the emitter electrode 15 and the emitter electrode 18 are formed by filling a conductive material into the space remaining inside the trench 61 and the space remaining inside the trench 62. The emitter electrode 18 may be formed separately from the emitter electrode 15.

As shown in FIG. 5B, the insulating layer 80 is removed by photolithography and etching to leave a portion 80a inside the trench 61 and a portion 80b inside the trench 62.

An insulating layer 81 that is used to form a portion of the insulating film 41 and a portion of the insulating film 42 is formed on the n-type semiconductor substrate 21f. A portion of the insulating layer 81 is provided along the inner wall of the trench 61. One other portion of the insulating layer 81 is provided along the inner wall of the trench 62. The thickness of the insulating layer 81 is set to be thinner than the thickness of the insulating layer 80. Thereby, the distance L1 is longer than the distance L2; the distance L3 is longer than the distance L4; the distance L5 is longer than the distance L6; and the distance L7 is longer than the distance L8.

As shown in FIG. 5C, the gate electrode 13, the gate electrode 14, the gate electrode 16, and the gate electrode 17 are formed by filling a conductive material into the spaces remaining inside the trench 61 and the spaces remaining inside the trench 62. The gate electrode 13, the gate electrode 14, the gate electrode 16, and the gate electrode 17 may be formed individually.

The insulating film 54 and the insulating film 55 are formed as shown in FIG. 5D. The insulating film 54 and the insulating film 55 are formed by, for example, forming an insulating layer that is thicker than the insulating layer 81 on the insulating layer 81 and by removing a portion of the insulating layer and a portion of the insulating layer 81 by photolithography and etching. Thereby, the insulating film 41 is formed of the portion 80a and a portion of the insulating layer 81; and the insulating film 42 is formed of the portion 80b and one other portion of the insulating layer 81.

As shown in FIG. 5E, the p⁺ collector layer 50 is formed in the region of the n-type semiconductor substrate 21f on the lower side by, for example, ion implantation. Thereby, the n⁻ base layer 21 is formed from the n-type semiconductor substrate 21f. For example, the p⁺ collector layer 50 may be formed under the n-type semiconductor substrate 21f by epitaxial growth.

As shown in FIG. 5F, the emitter electrode 12 is formed on the n⁺ emitter layer 24, the p⁺ contact layer 51, the insulating film 54, and the insulating film 55 by, for example, sputtering, etc. For example, the collector electrode 11 is formed under the p⁺ collector layer 50 by sputtering, etc.

Thus, the IGBT 110 is completed.

A first variation of the first embodiment will now be described.

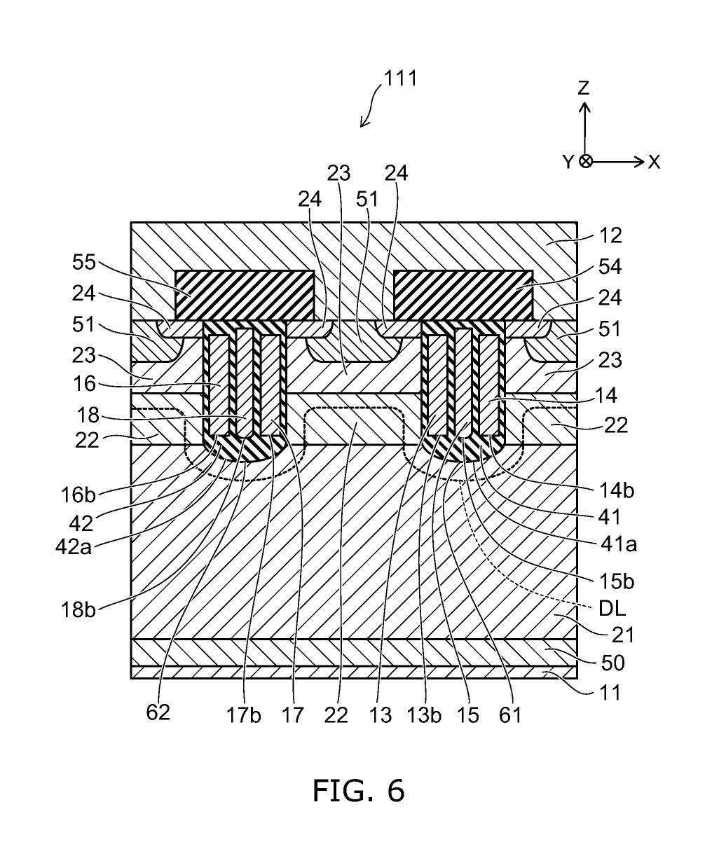

FIG. 6 is a schematic cross-sectional view illustrating the first variation of the power semiconductor device according to the first embodiment.

In the IGBT 111 as shown in FIG. 6, the lower end 13b of the gate electrode 13 is positioned lower than the p base layer 23 and higher than the n⁻ base layer 21. The lower end 14b of the gate electrode 14 is positioned lower than the p base layer 23 and higher than the n⁻ base layer 21. The lower end 15b of the emitter electrode 15 is positioned lower than the p base layer 23 and higher than the n⁻ base layer 21. The lower end 16b of the gate electrode 16 is positioned lower than the p base layer 23 and higher than the n⁻ base layer 21. The lower end 17b of the gate electrode 17 is positioned lower than the p base layer 23 and higher than the n⁻ base layer 21. The lower end 18b of the emitter electrode 18 is positioned lower than the p base layer 23 and higher than the n⁻ base layer 21. In other words, the Z-axis direction positions (heights) of the lower end 13b, the lower end 14b, the lower end 15b, the lower end 16b, the lower end 17b, and the lower end 18b are within the Z-axis direction thickness of the n barrier layer 22.

In the IGBT 111 as well, similarly to the IGBT 110, a power semiconductor device having good switching characteristics and a low on-voltage is obtained. The lengths along the Z-axis direction of the gate electrode 13, the gate electrode 14, the emitter electrode 15, the gate electrode 16, the gate electrode 17, and the emitter electrode 18 can be relatively shorter for the IGBT 111 than for the IGBT 110. Therefore, the configuration of the IGBT 111 can be simpler than the configuration of the IGBT 110. For example, the manufacturing time can be reduced. For example, the yield can be increased. On the other hand, for example, the avalanche energy can be higher for the IGBT 110 than for the IGBT 111.

In the IGBT 111, a voltage is applied between the collector electrode 11 and the emitter electrode 12. Thereby, a depletion layer DL extends toward the collector electrode 11 from the pn junction portion between the n barrier layer 22 and the p base layer 23.

The concentration of the impurity of the n barrier layer 22 is higher than that of the n⁻ base layer 21; and it is more difficult for the depletion layer DL to extend in the n barrier layer 22 than in the n⁻ base layer 21. Further, in the IGBT 111, the lower end 13b, the lower end 14b, the lower end 15b, the lower end 16b, the lower end 17b, and the lower end 18b are positioned higher than the n⁻ base layer 21. Therefore, in the IGBT 111, an electric field is not applied easily to the n⁻ base layer 21; and the depletion layer DL does not extend easily in the n⁻ base layer 21 as well. In the IGBT 111, the electric field easily concentrates in the n barrier layer 22; and avalanche breakdown occurs easily in the n barrier layer 22.

In the IGBT 110, the lower end 13b, the lower end 14b, the lower end 15b, the lower end 16b, the lower end 17b, and the lower end 18b are positioned lower than the n barrier layer 22. In the IGBT 110, the portion of the depletion layer DL that extends from the vicinity of the lower end 13b of the gate electrode 13 toward the gate electrode 17 gradually approaches the portion of the depletion layer DL that extends from the vicinity of the lower end 17b of the gate electrode 17 toward the gate electrode 13. Finally, the two portions contact each other. Thereby, the depletion layer DL can be thicker in the IGBT 110 than in the IGBT 111 (referring to FIG. 1). Thereby, the breakdown voltage can be higher for the IGBT 110 than for the IGBT 111.

Also, in the IGBT 110, the fluctuation of the Z-axis direction position of the depletion layer DL is suppressed by the contact between the portion extending from the gate electrode 13 toward the gate electrode 17 and the portion extending from the gate electrode 17 toward the gate electrode 13. Thereby, the concentration of the localized electric field can be suppressed and the avalanche energy can be increased more for the IGBT 110 than for the IGBT 111.

A second variation of the first embodiment will now be described.

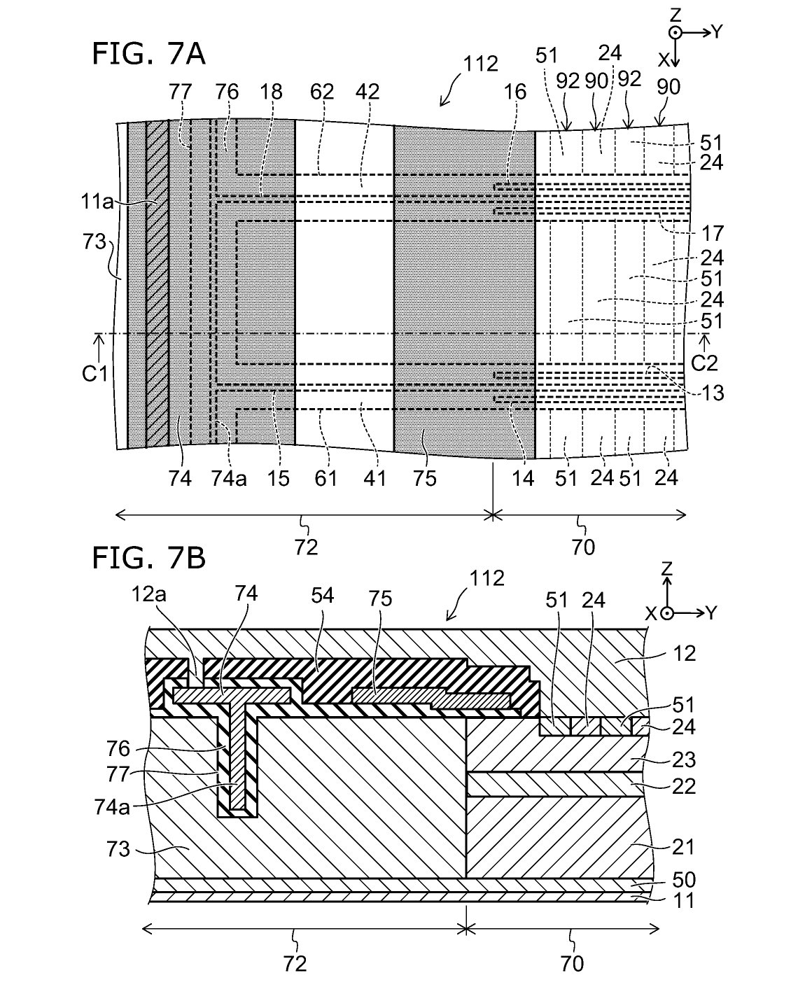

FIG. 7A and FIG. 7B are schematic views illustrating the second variation of the power semiconductor device according to the first embodiment.

FIG. 7A is a schematic plan view. FIG. 7B is a schematic cross-sectional view. FIG. 7B shows a cross section along line C1-C2 of FIG. 7A.

As shown in FIGS. 7A and 7B, an n⁺ emitter unit 90 that includes the n⁺ emitter layer 24, and a p⁺ contact unit 92 that includes the p⁺ contact layer 51 are provided in the IGBT 112.

In the n⁺ emitter unit 90, the n⁺ emitter layer 24 extends in the X-axis direction (a second direction). In the p⁺ contact unit 92, the p⁺ contact layer 51 extends in the X-axis direction. In other words, in the IGBT 112, the n⁺ emitter unit 90 and the p⁺ contact unit 92 extend in a direction that is orthogonal to the trench 61 and the trench 62.

The IGBT 112 includes multiple n⁺ emitter units 90 and multiple p⁺ contact units 92. The multiple n⁺ emitter units 90 and the multiple p⁺ contact units 92 are arranged alternately in the Y-axis direction (a first direction) in the device region 70. In other words, the multiple n⁺ emitter layers 24 and the multiple p⁺ contact layers 51 are arranged alternately in the Y-axis direction in the device region 70.

The n⁺ emitter layers 24 and the p⁺ contact layers 51 can be more efficiently disposed in the device region 70 in the IGBT 112 than in the IGBT 110. Thereby, the localized concentration of the electric field can be suppressed more appropriately and the breakdown voltage can be increased further in the IGBT 112 than in, for example, the IGBT 110.

### Second Embodiment

A second embodiment will now be described.

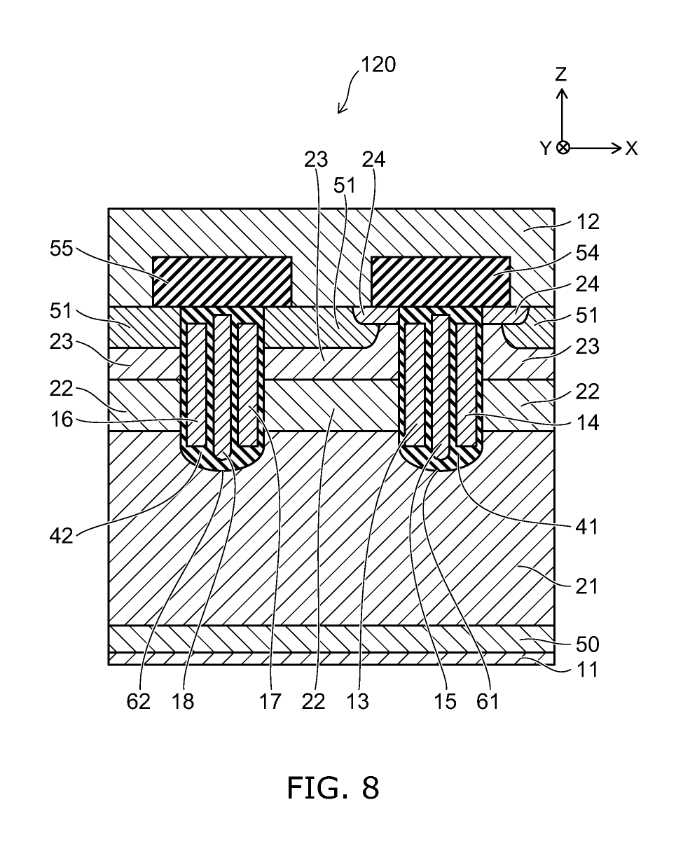

FIG. 8 is a schematic cross-sectional view illustrating a power semiconductor device according to the second embodiment.

In the IGBT 120 as shown in FIG. 8, the n⁺ emitter layer 24 on the trench 62 side is omitted. Also, in the IGBT 120, the p⁺ contact layer 51 contacts the insulating film 42 in the X-axis direction. In the IGBT 120, the electrode 16, the electrode 17, and the electrode 18 are electrically connected to the emitter electrode 12. Therefore, in the IGBT 120, it is unnecessary to provide the n⁺ emitter layer 24 on the trench 62 side.

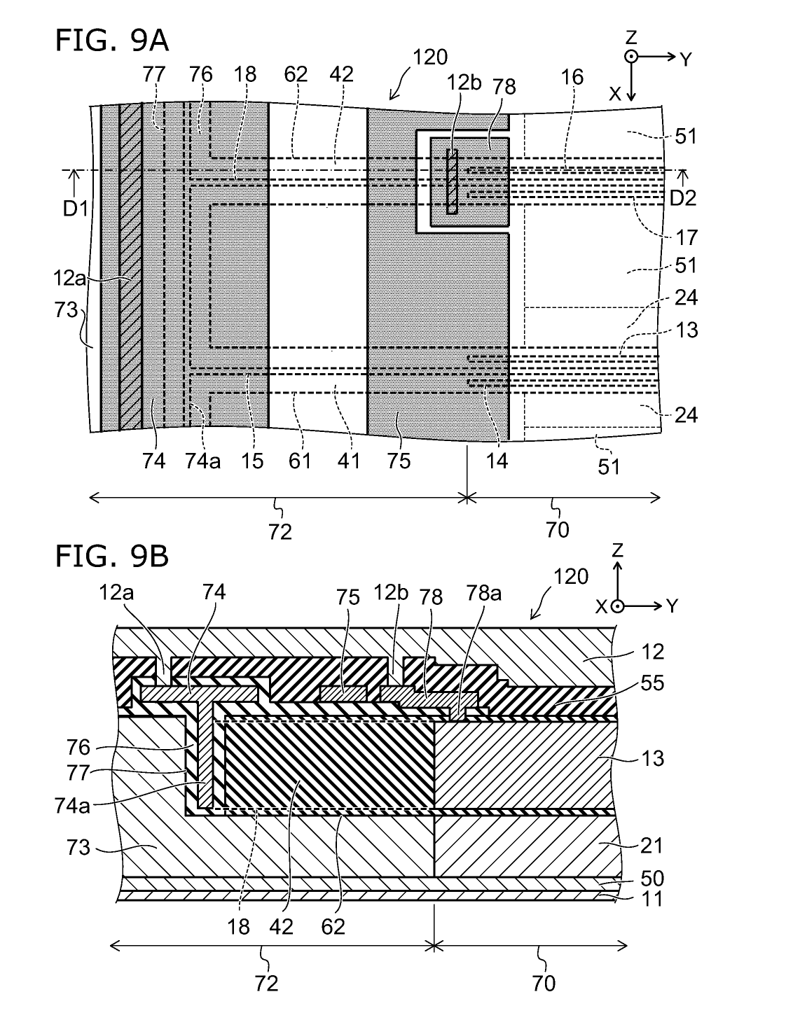

FIG. 9A and FIG. 9B are schematic views illustrating the power semiconductor device according to the second embodiment.

FIG. 9A is a schematic plan view. FIG. 9B is a schematic cross-sectional view. FIG. 9B shows a cross section along line D1-D2 of FIG. 9A.

As shown in FIG. 9A and FIG. 9B, the IGBT 120 includes an emitter interconnect 78.

The emitter interconnect 78 is provided between the emitter electrode 12 and the p-type layer 73. The emitter interconnect 78 is disposed to be separated from the emitter interconnect 74 and the gate interconnect 75. Also, the emitter interconnect 78 is provided on a portion of the electrode 16 and on a portion of the electrode 17. The emitter interconnect 78 may include, for example, a conductive material such as polysilicon, etc.

Insulating layers such as the insulating film 54, the insulating film 55, the terminal insulating film 76, etc., are provided between the emitter electrode 12 and the emitter interconnect 78. A plug portion 12b is provided in the emitter electrode 12. The plug portion 12b extends along the Z-axis direction to contact the emitter interconnect 78. For example, the plug portion 12b pierces the insulating layer provided between the emitter electrode 12 and the emitter interconnect 78. Thereby, the emitter interconnect 78 is electrically connected to the emitter electrode 12.

The terminal insulating film 76 and the insulating film 42 are provided between the emitter interconnect 78 and the electrode 16. The terminal insulating film 76 and the insulating film 42 are provided between the emitter interconnect 78 and the electrode 17. A plug portion 78a is provided in the emitter interconnect 78 to extend along the Z-axis direction to contact the electrode 16. Also, a plug portion (not shown) is provided in the emitter interconnect 78 to extend along the Z-axis direction to contact the electrode 17. Thereby, the electrode 16 and the electrode 17 are electrically connected to the emitter electrode 12 via the emitter interconnect 78 in the terminal region 72.

In the IGBT 120 as well, similarly to the IGBT 110, a power semiconductor device having good switching characteristics and a low on-voltage can be obtained. For example, a voltage of 15 V is applied to the gate electrode 13 and the gate electrode 14. On the other hand, for example, the emitter electrode 15, the electrode 16, the electrode 17, and the electrode 18 are grounded. Therefore, in the IGBT 120, the holes from the collector electrode 11 toward the emitter electrode 12 are attracted by the electrodes 16 to 18. Thereby, in the IGBT 120, the holes flowing through the vicinity of the gate electrode 13 and the vicinity of the gate electrode 14 can be reduced; and the oscillation of the gate voltage can be suppressed more appropriately. Also, the concentration of the impurity of the n barrier layer 22 can be increased.

A variation of the second embodiment will now be described.

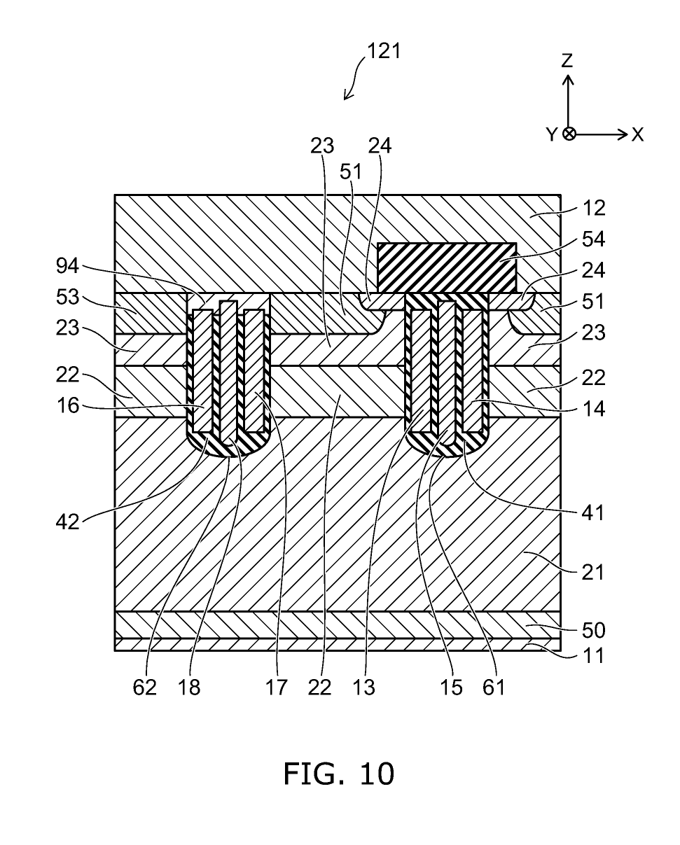

FIG. 10 is a schematic cross-sectional view illustrating the variation of the power semiconductor device according to the second embodiment.

As shown in FIG. 10, the IGBT 121 includes a conductive unit 94. The conductive unit 94 is provided between the emitter electrode 12 and the electrode 16, between the emitter electrode 12 and the electrode 17, and between the emitter electrode 12 and the electrode 18. The conductive unit 94 extends in the Y-axis direction along the electrodes 16 to 18 in the device region 70. The conductive unit 94 may include, for example, a conductive material such as aluminum, etc. The conductive unit 94 electrically connects the emitter electrode 12, the electrode 16, the electrode 17, and the electrode 18 to each other.

In the IGBT 121, the electrode 16, the electrode 17, and the electrode 18 are electrically connected to the emitter electrode 12 in the device region 70 by the conductive unit 94. In other words, the electrode 16, the electrode 17, and the electrode 18 are electrically connected to the emitter electrode 12 directly above the electrode 16, the electrode 17, and the electrode 18. Thereby, in the IGBT 121, the displacement current flowing in the electrode 16 and/or the electrode 17 can be caused to flow more smoothly in the emitter electrode 12; and the stability of the switching can be increased further. The electrode 16, the electrode 17, and the electrode 18 may directly contact the emitter electrode 12 without the conductive unit 94 being interposed.

### Third Embodiment

A third embodiment will now be described.

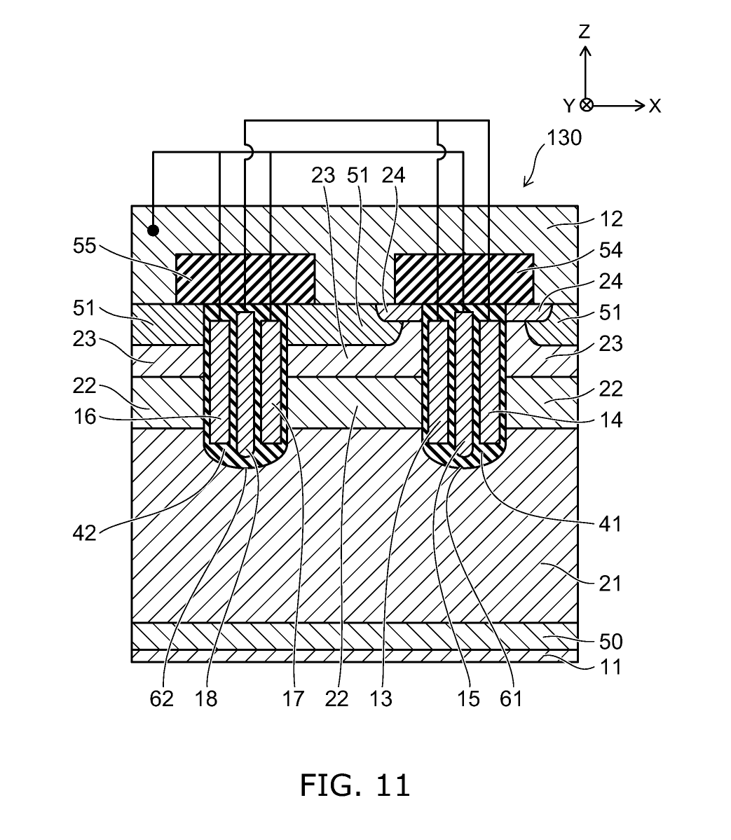

FIG. 11 is a schematic cross-sectional view illustrating a power semiconductor device according to the third embodiment.

In the IGBT 130 as shown in FIG. 11, the electrode 16 and the electrode 17 are electrically connected to the emitter electrode 12; and the electrode 18 is electrically connected to the gate electrode 13 and the gate electrode 14.

Although the occurrence of the displacement current is suppressed more for the IGBT 120 and the IGBT 121 than for the IGBT 110, the capacitance Cge in the IGBT 120 and the IGBT 121 is undesirably smaller than that of the IGBT 110. Conversely, the occurrence of the displacement current is suppressed in the IGBT 130 similarly to the IGBT 120 and the IGBT 121; and a capacitance Cge that is about the same as that of the IGBT 110 can be provided due to the parasitic capacitance occurring between the electrode 16 and the electrode 18 and the parasitic capacitance occurring between the electrode 17 and the electrode 18. Thereby, the oscillation of the gate voltage can be suppressed more appropriately in the IGBT 130.

An IGBT having a trench-gate structure is illustrated as the power semiconductor device in the embodiments recited above. The power semiconductor device may be, for example, a MOSFET having a trench-gate structure. In the case of the MOSFET, for example, the first electrode is used as the source electrode; the second electrode is used as the drain electrode; the fourth semiconductor layer is used as the n source layer; and the p⁺ collector layer 50 is used as the n⁺ drain layer.

According to the embodiments, a power semiconductor device having good switching characteristics and a low on-voltage is provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in power semiconductor devices such as the first to the eighth electrode, the first to the fourth semiconductor layer, the device region, the termination region, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all power semiconductor devices practicable by an appropriate design modification by one skilled in the art based on the power semiconductor devices above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a first electrode having a first face and a second face;
a first semiconductor layer of a first conductivity type provided on a side of the first face of the first electrode;
a second semiconductor layer of the first conductivity type provided on the first semiconductor layer, a concentration of an impurity of the second semiconductor layer being higher than a concentration of an impurity of the first semiconductor layer;
a third semiconductor layer of a second conductivity type provided on the second semiconductor layer;
a fourth semiconductor layer of the first conductivity type provided on the third semiconductor layer;
a second electrode electrically connected to the fourth semiconductor layer;
a third electrode provided at the second semiconductor layer and the third semiconductor layer with an insulating film interposed between the third electrode and the second semiconductor layer and between the third electrode and the third semiconductor layer, the third electrode extending in a stacking direction of the first semiconductor layer and the second semiconductor layer to have an upper end positioned at the third semiconductor layer;
a fourth electrode arranged with the third electrode to be provided at the second semiconductor layer and the third semiconductor layer with an insulating film interposed between the fourth electrode and the second semiconductor layer and between the fourth electrode and the third semiconductor layer, the fourth electrode extending in the stacking direction to have an upper end positioned at the third semiconductor layer; and
a fifth electrode provided between the third electrode and the fourth electrode with an insulating film interposed between the fifth electrode and the third electrode and between the fifth electrode and the fourth electrode, the fifth electrode being electrically connected to the second electrode and extending in the stacking direction to have an upper end positioned at the third semiconductor layer.

2. The device according to claim 1, wherein
a first distance between the first semiconductor layer and a lower end of the third electrode is longer than a second distance between the third electrode and the third semiconductor layer, and
a third distance between the first semiconductor layer and a lower end of the fourth electrode is longer than a fourth distance between the fourth electrode and the third semiconductor layer.

3. The device according to claim 2, wherein
the absolute value of the difference between the first distance and the third distance is not more than 5 nm, and
the absolute value of the difference between the second distance and the fourth distance is not more than 5 nm.

4. The device according to claim 1, wherein a lower end of the third electrode is positioned lower than the second semiconductor layer, and a lower end of the fourth electrode is positioned lower than the second semiconductor layer.

5. The device according to claim 4, wherein a lower end of the fifth electrode is positioned lower than the lower end of the third electrode and the lower end of the fourth electrode.

6. The device according to claim 1, further comprising:
a sixth electrode provided at the second semiconductor layer and the third semiconductor layer with an insulating film interposed between the sixth electrode and the second semiconductor layer and between the sixth electrode and the third semiconductor layer, the sixth electrode extending in the stacking direction to have an upper end positioned at the third semiconductor layer;
a seventh electrode arranged with the sixth electrode to be provided at the second semiconductor layer and the third semiconductor layer with an insulating film interposed between the seventh electrode and the second semiconductor layer and between the seventh electrode and the third semiconductor layer, the seventh electrode extending in the stacking direction to have an upper end positioned at the third semiconductor layer; and
an eighth electrode provided between the sixth electrode and the seventh electrode with an insulating film interposed between the eighth electrode and the sixth electrode and between the eighth electrode and the seventh electrode, the eighth electrode extending in the stacking direction to have an upper end positioned at the third semiconductor layer.

7. The device according to claim 6, wherein
the sixth electrode and the seventh electrode are electrically connected to the third electrode, and
the eighth electrode is electrically connected to the second electrode.

8. The device according to claim 6, wherein the sixth electrode, the seventh electrode, and the eighth electrode are electrically connected to the second electrode.

9. The device according to claim 8, further comprising:
a device region including the first semiconductor layer, the second semiconductor layer, the third semiconductor layer, and the fourth semiconductor layer; and
a terminal region provided around the device region by being provided around an axis extending in a stacking direction from the first semiconductor layer toward the fourth semiconductor layer,
the sixth electrode, the seventh electrode, and the eighth electrode being electrically connected to the second electrode in the device region.

10. The device according to claim 6, wherein
the sixth electrode and the seventh electrode are electrically connected to the second electrode, and
the eighth electrode is electrically connected to the third electrode.

11. The device according to claim 6, wherein a lower end of the sixth electrode is positioned lower than the second semiconductor layer, and a lower end of the seventh electrode is positioned lower than the second semiconductor layer.

12. The device according to claim 11, wherein a lower end of the eighth electrode is positioned lower than the lower end of the sixth electrode and the lower end of the seventh electrode.

13. The device according to claim 6, wherein
a fifth distance between the first semiconductor layer and a lower end of the sixth electrode is longer than a sixth distance between the sixth electrode and the third semiconductor layer, and
a seventh distance between the first semiconductor layer and a lower end of the seventh electrode is longer than an eighth distance between the seventh electrode and the third semiconductor layer.

14. The device according to claim 13, wherein
the absolute value of the difference between the fifth distance and the seventh distance is not more than 5 nm, and
the absolute value of the difference between the sixth distance and the eighth distance is not more than 5 nm.

15. The device according to claim 1, wherein a concentration of an impurity of the fourth semiconductor layer is higher than the concentration of the impurity of the first semiconductor layer.

16. The device according to claim 1, further comprising a fifth semiconductor layer of the second conductivity type provided between the first electrode and the second electrode.

17. The device according to claim 1, further comprising a contact layer of the second conductivity type provided between the second electrode and the third semiconductor layer,
a concentration of an impurity of the contact layer being higher than a concentration of an impurity of the third semiconductor layer.

18. The device according to claim 17, wherein
the third electrode, the fourth electrode, and the fifth electrode extend in a first direction perpendicular to the stacking direction,
the fourth semiconductor layer is provided in a plurality,
each of the fourth semiconductor layers extends in a second direction perpendicular to the stacking direction and the first direction,
the contact layer is provided in a plurality,
each of the contact layers extends in the second direction, and
the fourth semiconductor layers and the contact layers are arranged alternately in the first direction.

19. The device according to claim 1, wherein
a lower end of the third electrode is positioned lower than the third semiconductor layer and higher than the first semiconductor layer,
a lower end of the fourth electrode is positioned lower than the third semiconductor layer and higher than the first semiconductor layer, and
a lower end of the fifth electrode is positioned lower than the third semiconductor layer and higher than the first semiconductor layer.

20. The device according to claim 6, wherein
a lower end of the sixth electrode is positioned lower than the third semiconductor layer and higher than the first semiconductor layer,
a lower end of the seventh electrode is positioned lower than the third semiconductor layer and higher than the first semiconductor layer, and
a lower end of the eighth electrode is positioned lower than the third semiconductor layer and higher than the first semiconductor layer.
